(19) United States
(12) Patent Application Publication
(10) Pub. No.: US 2025/0393235 A1
(43) Pub. Date: Dec. 25, 2025

(54) INTEGRATED CIRCUIT PROVIDING VARIOUS CHANNEL LENGTHS

(71) Applicant: SAMSUNG ELECTRONICS CO., LTD., Suwon-si (KR)

(72) Inventors: Hankyung Kim, Suwon-si (KR); Seungkwon Lee, Suwon-si (KR); Hana Kim, Suwon-si (KR)

(73) Assignee: SAMSUNG ELECTRONICS CO., LTD., Suwon-si (KR)

(21) Appl. No.: 19/022,741

(22) Filed: Jan. 15, 2025

(30) Foreign Application Priority Data
Jun. 20, 2024 (KR) 10-2024-0080590

(51) Int. Cl. H10D 30/43; H10D 30/00; H10D 62/10; H10D 64/23; H10D 84/85

(52) U.S. Cl. CPC H10D 30/43; H10D 30/501; H10D 62/121; H10D 64/251; H10D 84/852

(57) ABSTRACT

An integrated circuit includes: a first device region and a second device region extending parallel to each other on a substrate in a first direction; a first gate electrode extending in a second direction and intersecting with the first device region and the second device region; a first transistor including the first gate electrode and a first channel having a first conductive-type in the first device region; and a second transistor including the first gate electrode and a second channel having the first conductive-type in the second device region, wherein a first source/drain region of the first transistor is electrically connected to a first source/drain region of the second transistor, and wherein a second source/drain region of the first transistor is electrically disconnected from a second source/drain region of the second transistor.

### CROSS-REFERENCE TO RELATED APPLICATION

This application is based on and claims priority under 35 U.S.C. § 119 to Korean Patent Application No. 10-2024-0080590, filed on Jun. 20, 2024, in the Korean Intellectual Property Office, the disclosure of which is incorporated by reference herein in its entirety.

### BACKGROUND

The disclosure relates to an integrated circuit, and more particularly, to an integrated circuit including various channel lengths.

Along with the development of a semiconductor process, the sizes of devices included in an integrated circuit may decrease, and the degree of integration of the integrated circuit may increase. The integrated circuit may include a digital circuit (such as a logic gate, configured to process a digital signal), an analog circuit (such as an amplifier, configured to process an analog signal), and a mixed circuit (such as an analog-digital converter, configured to process an analog signal and a digital signal). The analog circuit and the mixed circuit configured to process an analog signal may require devices having various characteristics, for example, transistors having various channel lengths. Accordingly, it may be essential to efficiently integrate devices having various characteristics in an integrated circuit through a semiconductor process.

### SUMMARY

Provided is an integrated circuit including various channel lengths.

According to an aspect of the disclosure, an integrated circuit includes: a first device region and a second device region extending parallel to each other on a substrate in a first direction; a first gate electrode extending in a second direction and intersecting with the first device region and the second device region; a first transistor including the first gate electrode and a first channel having a first conductive-type in the first device region; and a second transistor including the first gate electrode and a second channel having the first conductive-type in the second device region, wherein a first source/drain region of the first transistor is electrically connected to a first source/drain region of the second transistor, and wherein a second source/drain region of the first transistor is electrically disconnected from a second source/drain region of the second transistor.

The integrated circuit further includes: a second gate electrode extending in the second direction and intersecting with the first device region and the second device region; a third transistor comprising the second gate electrode and a third channel having the first conductive-type in the first device region; and a fourth transistor comprising the second gate electrode and a fourth channel having the first conductive-type in the second device region.

he integrated circuit further includes: a third transistor comprising the second gate electrode and a third channel having the first conductive-type in the first device region, and a fourth transistor comprising the second gate electrode and the fourth channel having the first conductive-type in the second device region.

The integrated circuit further includes: a third transistor comprising the second gate electrode and a third channel having a second conductive-type in the first device region, and a fourth transistor comprising the second gate electrode and a fourth channel having the second conductive-type in the second device region.

According to an aspect of the disclosure, an integrated circuit includes: a first device region extending on a substrate in a first direction; a first gate electrode and a second gate electrode extending in a second direction, being parallel to each other, and intersecting with the first device region; a first transistor including the first gate electrode and a first channel having a first conductive-type in the first device region; and a second transistor including the second gate electrode and a second channel having the first conductive-type in the first device region, wherein the first transistor and the second transistor are configured to share a first source/drain region between the first gate electrode and the second gate electrode, and wherein the first gate electrode is electrically connected to the second gate electrode.

The integrated circuit may further includes: a third gate electrode extending in the second direction and intersecting with the first device region; a third transistor comprising the third gate electrode and a third channel having the first conductive-type channel in the first device region, wherein the second transistor and the third transistor are configured to share a source/drain region between the second gate electrode and the third gate electrode, and wherein the third gate electrode is electrically connected to the second gate electrode.

The integrated circuit may further includes: a third transistor comprising the third gate electrode and a third channel having the first conductive-type in the first device region.

The integrated circuit may further includes: a third transistor comprising the third gate electrode and a third channel having a second conductive-type in the first device region.

According to an aspect of the disclosure, an integrated circuit includes: a first transistor and a second transistor having a first conductive-type channel and connected in series to each other; and a third transistor and a fourth transistor having a second conductive-type channel and connected in series to each other, wherein a first gate of the first transistor and a second gate of the second transistor are electrically connected to a first node, and wherein a third gate of the third transistor and a fourth gate of the fourth transistor are electrically connected to a second node.

### BRIEF DESCRIPTION OF THE DRAWINGS

Embodiments of the disclosure will be more clearly understood from the following detailed description taken in conjunction with the accompanying drawings in which:

FIGS. 1A and 1B are circuit diagrams illustrating integrated circuits according to embodiments;

FIGS. 2A to 2D are perspective views illustrating transistors according to embodiments;

FIG. 3 is a top view illustrating a layout of an integrated circuit according to an embodiment;

FIGS. 4A to 4D illustrate a layout of an integrated circuit according to an embodiment;

FIGS. 5A to 5C illustrate a layout of an integrated circuit according to an embodiment;

FIGS. 6A and 6B are top views illustrating layouts of integrated circuits according to embodiments;

FIG. 7 is a top view illustrating a layout of an integrated circuit according to an embodiment;

FIGS. 8A and 8B are top views illustrating layouts of integrated circuits according to embodiments;

FIGS. 9A and 9B are top views illustrating layouts of integrated circuits according to embodiments;

FIG. 10 is a top view illustrating a layout of an integrated circuit according to an embodiment; and

FIG. 11 is a block diagram illustrating a system on chip (SoC) according to an embodiment.

### DETAILED DESCRIPTION

The terms as used in the disclosure are provided to merely describe specific embodiments, not intended to limit the scope of other embodiments. Singular forms include plural referents unless the context clearly dictates otherwise. The terms and words as used herein, including technical or scientific terms, may have the same meanings as generally understood by those skilled in the art. The terms as generally defined in dictionaries may be interpreted as having the same or similar meanings as or to contextual meanings of the relevant art. Unless otherwise defined, the terms should not be interpreted as ideally or excessively formal meanings. Even though a term is defined in the disclosure, the term should not be interpreted as excluding embodiments of the disclosure under circumstances.

The terms “include” and “comprise”, and the derivatives thereof refer to inclusion without limitation. The term “or” is an inclusive term meaning “and/or”. The phrase “associated with,” as well as derivatives thereof, refer to include, be included within, interconnect with, contain, be contained within, connect to or with, couple to or with, be communicable with, cooperate with, interleave, juxtapose, be proximate to, be bound to or with, have, have a property of, have a relationship to or with, or the like. The term “controller” refers to any device, system, or part thereof that controls at least one operation. The functionality associated with any particular controller may be centralized or distributed, whether locally or remotely. The phrase “at least one of,” when used with a list of items, means that different combinations of one or more of the listed items may be used, and only one item in the list may be needed. For example, “at least one of A, B, and C” includes any of the following combinations: A, B, C, A and B, A and C, B and C, and A and B and C, and any variations thereof. As an additional example, the expression “at least one of a, b, or c” may indicate only a, only b, only c, both a and b, both a and c, both b and c, all of a, b, and c, or variations thereof. Similarly, the term “set” means one or more. Accordingly, the set of items may be a single item or a collection of two or more items.

In the disclosure, in order to determine whether a specific condition is satisfied or fulfilled, an expression of more than or less than may be used, but this is only a description for expressing an example, and does not exclude description of more than or equal to or less than or equal to. A condition described as ‘more than or equal to’ may be replaced with ‘more than’, a condition described as ‘less than or equal to’ may be replaced with ‘less than’, and a condition described as ‘more than or equal to and less than’ may be replaced with ‘more than and less than or equal to’.

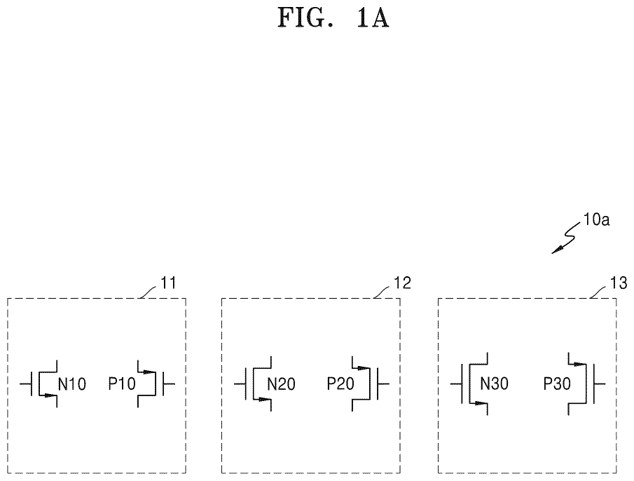

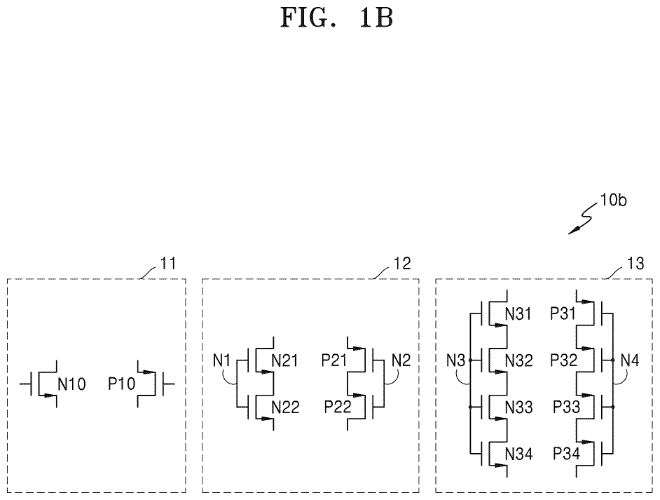

FIGS. 1A and 1B are circuit diagrams illustrating integrated circuits 10a and 10b according to embodiments. For example, the circuit diagram of FIG. 1A shows some of devices included in the integrated circuit 10a. The circuit diagram of FIG. 1B shows some of devices included in the integrated circuit 10b.

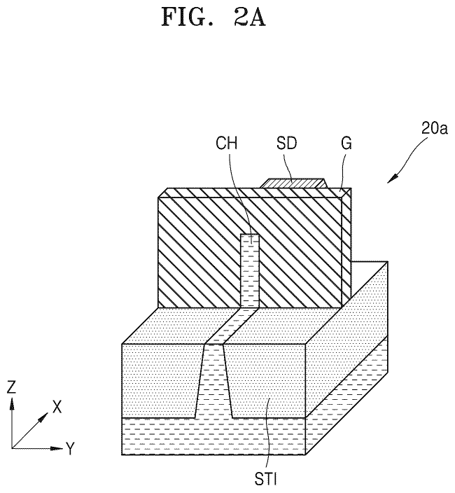

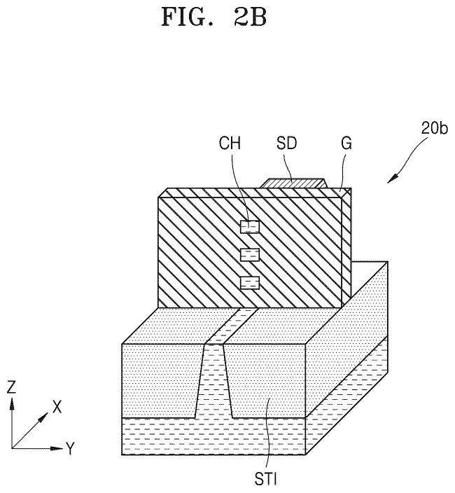

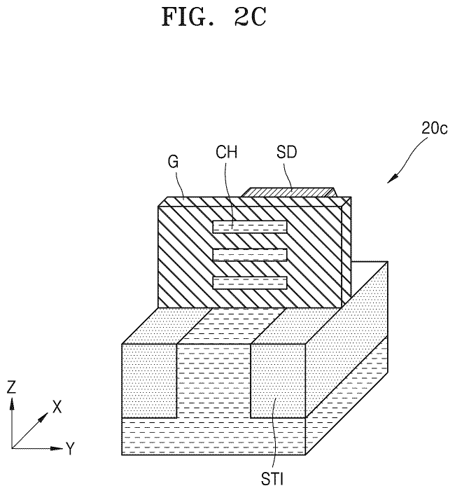

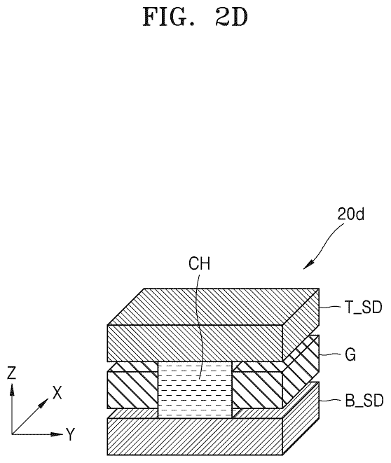

Referring to FIG. 1A, the integrated circuit 10a may include a first circuit 11, a second circuit 12, and a third circuit 13. In some embodiments, the first circuit 11, the second circuit 12, and the third circuit 13 may respectively include devices which process an analog signal and have different characteristics. For example, the first circuit 11, the second circuit 12, and the third circuit 13 may respectively include transistors having different channel lengths. A channel length may indicate the channel length of a transistor and, for example, may correspond to the distance between a source and a drain in a field effect transistor (FET) and may be proportional to a gate length. An analog circuit may require transistors having various channel lengths in accordance with circumstances, and the integrated circuit 10a may include transistors having various channel lengths. Examples of the transistor are described below with reference to FIGS. 2A to 2D.

As shown in FIG. 1A, the first circuit 11 may include a first n-channel field effect transistor (NFET) N10 and a first p-channel field effect transistor (PFET) P10. The second circuit 12 may include a second NFET N20 and a second PFET P20. The third circuit 13 may include a third NFET N30 and a third PFET P30. The first NFET N10 may have a shorter channel length than the second NFET N20 and the third NFET N30. The first PFET P10 may have a shorter channel length than the second PFET P20 and the third PFET P30. The second NFET N20 may have a shorter channel length than the third NFET N30. The second PFET P20 may have a shorter channel length than the third PFET P30. Herein, an NFET may be referred to as a transistor having a first conductive-type (or second conductive-type) channel, and a PFET may be referred to as a transistor having the second conductive-type (or first conductive-type) channel.

Due to a semiconductor process (for example, a local layout effect (LLE) or the like), a space between transistors having different channel lengths may be required. For example, when the first NFET N10 is adjacent to the second NFET N20 in the layout of the integrated circuit 10a, the first NFET N10 and/or the second NFET N20 may not be normally formed due to limitations of the semiconductor process. Or, the first NFET N10 and the second NFET N20 may not provide designed performance due to the LLE. Accordingly, in the layout of the integrated circuit 10a, a space may be required between the first NFET N10 and the second NFET N20, i.e., between the first circuit 11 and the second circuit 12. As a result, in the related art, the layout of the integrated circuit 10a including the first circuit 11, the second circuit 12, and the third circuit 13 may have low efficiency.

Referring to FIG. 1B, the integrated circuit 10b may include a first circuit 11, a second circuit 12, and a third circuit 13, which may respectively correspond to the first circuit 11, the second circuit 12, and the third circuit 13 of FIG. 1A. Unlike the integrated circuit 10a of FIG. 1A, which includes transistors having different channel lengths, the integrated circuit 10b of FIG. 1B may include transistors having a uniform channel length.

As shown in FIG. 1B, the first circuit 11 may include the first NFET N10 and the first PFET P10. The second circuit 12 may include second NFETs N21 and N22 and second PFETs P21 and P22. The third circuit 13 may include third NFETs N31 to N34 and third PFETs P31 to P34. The first NFET N10, the second NFETs N21 and N22, and the third NFETs N31 to N34 may have the same channel length.

In an embodiment, the first PFET P10, the second PFETs P21 and P22, and the third PFETs P31 to P34 may have the same channel length. Accordingly, in the layout of the integrated circuit 10b of FIG. 1B, a space among the first circuit 11, the second circuit 12, and the third circuit 13 may be removed or minimized. In some embodiments, the channel length of each of the first NFET N10, the second NFETs N21 and N22, and the third NFETs N31 to N34 may correspond to the minimum channel length of NFETs in the integrated circuit 10b, and the channel length of each of the first PFET P10, the second PFETs P21 and P22, and the third PFETs P31 to P34 may correspond to the minimum channel length of PFETs in the integrated circuit 10b.

In the second circuit 12, the second NFETs N21 and N22 may be connected in series to each other and respectively have gates connected to a node N1. Accordingly, the second NFETs N21 and N22 may provide an effective channel length corresponding to the channel length of the second NFET N20 of FIG. 1A. In an embodiment, in the second circuit 12, the second PFETs P21 and P22 may be connected in series to each other and respectively have gates connected to a node N2. Accordingly, the second PFETs P21 and P22 may provide an effective channel length corresponding to the channel length of the second PFET P20 of FIG. 1A.

In an embodiment, in the third circuit 13, the third NFETs N31 to N34 may be connected in series to each other and respectively have gates connected to a node N3. Accordingly, the third NFETs N31 to N34 may provide an effective channel length corresponding to the channel length of the third NFET N30 of FIG. 1A.

In an embodiment, in the third circuit 13, the third PFETs P31 to P34 may be connected in series to each other and respectively have gates connected to a node N4. Accordingly, the third PFETs P31 to P34 may provide an effective channel length corresponding to the channel length of the third PFET P30 of FIG. 1A.

As described above, the integrated circuit 10b may provide transistors having various channel lengths through uniform transistors. Accordingly, due to the various channel lengths, the integrated circuit 10b may provide an analog circuit having improved performance. In an embodiment, overhead for integrating transistors having various channel lengths may be reduced, and the area of the integrated circuit 10b may be reduced or the degree of integration of the integrated circuit 10b may be improved. In an embodiment, the layout of the integrated circuit 10b may have a uniform structure, and because variation is reduced, the integrated circuit 10b may provide improved reliability. Hereinafter, with reference to drawings, structures in which transistors having various channel lengths are provided by uniform transistors are described. Hereinafter, PFETs are mainly described, but it would be understood that embodiments are also applicable to NFETs.

FIGS. 2A to 2D are perspective views illustrating transistors according to embodiments. For example, FIG. 2A shows a fin-shaped field effect transistor (FinFET) 20a. FIG. 2B shows a gate-all-around field effect transistor (GAAFET) 20b. FIG. 2C shows a multi-bridge channel field effect transistor (MBCFET) 20c. FIG. 2D shows a vertical field effect transistor (VFET) 20d. FIGS. 2A to 2C show that one of two source/drain regions is removed. FIG. 2D shows a cross-section of the VFET 20d as a plane that is parallel to a plane formed by the Y axis and the Z axis and passes through a channel CH of the VFET 20d.

Referring to FIG. 2A, the FinFET 20a may be formed by a fin-shaped active pattern extending in the X-axis direction between shallow trench isolations (STIs) and a gate G extending in the Y-axis direction. A “source/drain SD” may be formed at (or included in) both sides of the gate G, and accordingly, a source and a drain may be spaced apart from each other in the X-axis direction. Throughout the disclosure, the term ‘source/drain SD’ indicates that an area of the source area S and another area of the drain area D can be interchangeable in the embodiments of the disclosure.

An insulating layer may be formed between a channel CH and the gate G. In some embodiments, the FinFET 20a may be formed by a plurality of active patterns spaced apart from each other in the X-axis direction and the gate G.

Referring to FIG. 2B, the GAAFET 20b may be formed by active patterns, i.e., nanowires, spaced apart from each other in the Z-axis direction and extending in the X-axis direction and the gate G extending in the Y-axis direction. The source/drain SD may be formed at both sides of the gate G, and accordingly, a source and a drain may be spaced apart from each other in the X-axis direction. An insulating layer may be formed between the channel CH and the gate G. The three rectangles shown in FIG. 2B (one rectangle indicated by ‘CH’) are the nanowires. The number of nanowires included in the GAAFET 20b of FIG. 2B is not limited to that shown in FIG. 2B.

Referring to FIG. 2C, the MBCFET 20c may be formed by active patterns, i.e., nanosheets, spaced apart from each other in the Z-axis direction and extending in the X-axis direction and the gate G extending in the Y-axis direction. The source/drain SD may be formed at both sides of the gate G, and accordingly, a source and a drain may be spaced apart from each other in the X-axis direction. An insulating layer may be formed between the channel CH and the gate G. The three rectangles shown in FIG. 2C (one rectangle indicated by ‘CH’) are the nanosheets. The number of nanosheets included in the MBCFET 20c of FIG. 2C is not limited to that shown in FIG. 2C.

Referring to FIG. 2D, the VFET 20d may include a top source/drain T_SD and a bottom source/drain B_SD spaced apart from each other in the Z-axis direction with the channel CH therebetween. The VFET 20d may include the gate G surrounding the perimeter of the channel CH between the top source/drain T_SD and the bottom source/drain B_SD. An insulating layer may be formed between the channel CH and the gate G.

Hereinafter, an integrated circuit including the FinFET 20a or the MBCFET 20c is mainly described, but devices included in the integrated circuit are not limited to the examples of FIGS. 2A to 2D. For example, the integrated circuit may include a ForkFET having a structure in which an N-type transistor is relatively close to a P-type transistor because nanosheets for the P-type transistor and nanosheets for the N-type transistor are separated by a dielectric wall. In an embodiment, the integrated circuit may include an FET (such as a complementary field effect transistor (CFET), a negative capacitance field effect transistor (NCFET), or a carbon nanotube (CNT) FET) and a bipolar junction transistor.

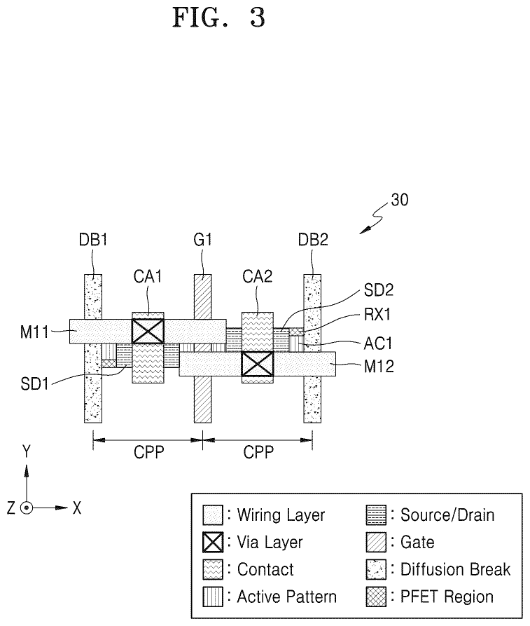

FIG. 3 is a top view illustrating a layout 30 of an integrated circuit according to an embodiment. For example, the top view of FIG. 3 shows the layout 30 including the first PFET P10 of FIG. 1B. Hereinafter, the layout 30 of FIG. 3 includes the first PFET P10 of FIG. 1B, and FIG. 3 is described with reference to FIG. 1B.

Herein, the X-axis direction and the Y-axis direction may be referred to as a first direction and a second direction, respectively, and the Z-axis direction may be referred to as the vertical direction or a third direction. The Z-axis direction may be perpendicular to (or substantially perpendicular to) the X-axis direction and the Y-axis direction.

A plane formed by the X axis and the Y axis may be referred to as a ‘horizontal plane.’ A component disposed relatively in the +Z direction than another component may be considered to be ‘above’ the other component, and a component disposed relatively in the −Z direction than another component may be considered to be ‘below’ the other component. In an embodiment, the ‘area’ of a component may indicate a ‘size’ occupied by the component on a plane parallel to the horizontal plane, and the ‘width’ of a component may indicate a ‘length’ of the component in a direction perpendicular to the direction in which the component extends.

A surface exposed in the +Z direction may indicate a ‘top’ surface, a surface exposed in the −Z direction may indicate a ‘bottom’ surface, and a surface exposed in the +X direction or the +Y direction may indicate a ‘side’ surface. In the drawings, only some layers may be shown, and a via connecting a higher pattern to a lower pattern may be shown even though the via is beneath the higher pattern. In an embodiment, a pattern, such as a pattern of a wiring layer, formed of a conductive material may be referred to as a ‘conductive pattern’ or simply as a ‘pattern.’

Referring to FIG. 3, the layout 30 may include a first device region RX1 extending in the X-axis direction. A first gate electrode G1 may extend in the Y-axis direction and intersect with the first device region RX1. The first gate electrode G1 may form (or include) the first PFET P10 in the first device region RX1. For example, as shown in FIG. 3, in the first device region RX1, a first active pattern AC1 may extend in the X-axis direction and intersect with the first gate electrode G1. A first source/drain SD1 and a second source/drain SD2 may be respectively at both sides of the first gate electrode G1. Accordingly, the first PFET P10 may have a ‘channel length’ corresponding to the width (i.e., the length in the X-axis direction) of the first gate electrode G1. In some embodiments, as described above with reference to FIG. 1B, the channel length of the first PFET P10 may correspond to the minimum channel length in the integrated circuit. In some embodiments, an analog signal may be applied to the first gate electrode G1.

A first contact CA1 and a second contact CA2 may be connected to the first source/drain SD1 and the second source/drain SD2, respectively, and extend in the Y-axis direction. A first pattern M11 of a first wiring layer M1 may be connected to the first contact CA1 through a via of a first via layer V0 and extend in the X-axis direction. In an embodiment, a second pattern M12 of the first wiring layer M1 may be connected to the second contact CA2 through a via of the first via layer V0 and extend in the X-axis direction. Vias may be on the first pattern M11 and the second pattern M12. The first pattern M11 and the second pattern M12 may be connected to patterns of a higher wiring layer through the vias. In some embodiments, the first wiring layer M1 may be a wiring layer closest to a gate electrode.

A first diffusion break DB1 and a second diffusion break DB2 may extend in the Y-axis direction and intersect with the first device region RX1. As shown in FIG. 3, the first gate electrode G1 may extend in the Y-axis direction between the first diffusion break DB1 and the second diffusion break DB2. As shown in FIG. 3, the first gate electrode G1, the first diffusion break DB1, and the second diffusion break DB2 may extend in the Y-axis direction at the same pitch CPP therebetween. The first diffusion break DB1 and the second diffusion break DB2 may include an insulating material and isolate the first PFET P10 from the other PFETs formed in the first device region RX1. Like the first diffusion break DB1 and the second diffusion break DB2, a diffusion break substituting for a gate electrode may be referred to as a single diffusion break (SDB).

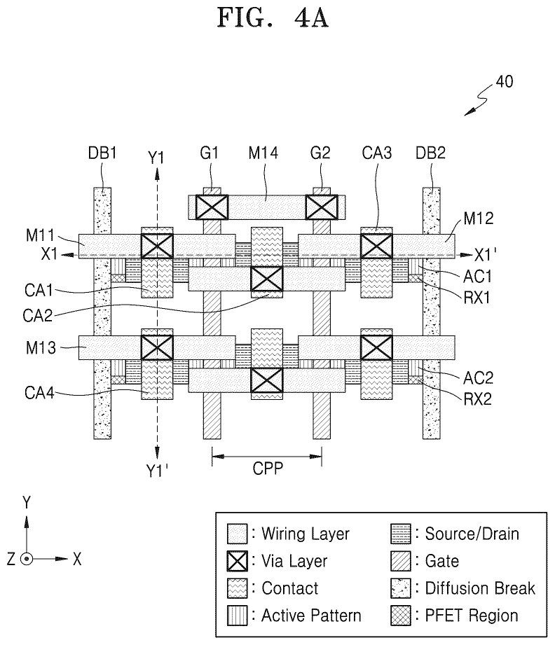

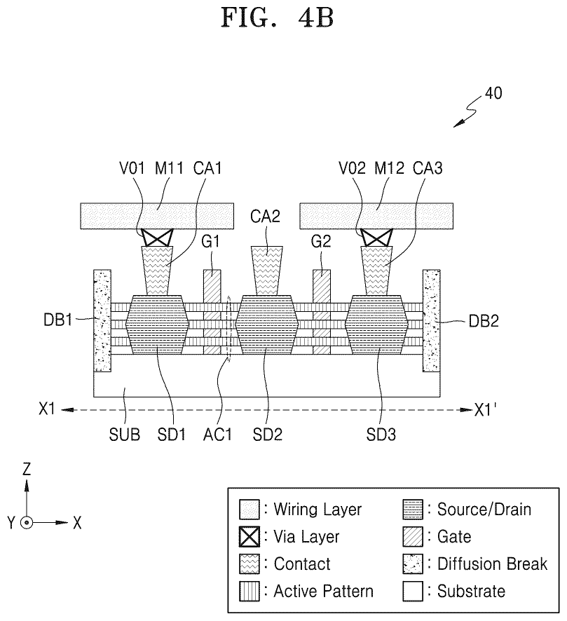

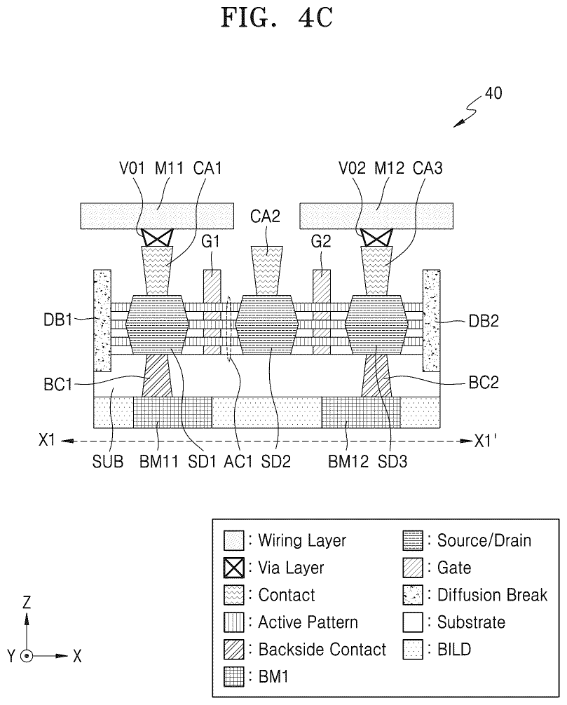

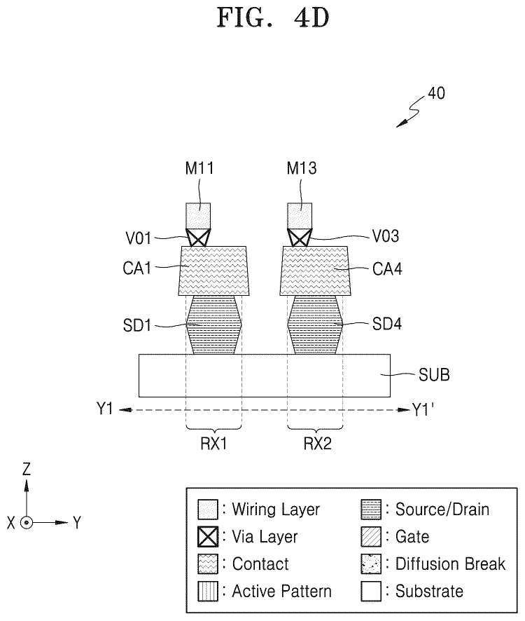

FIGS. 4A to 4D illustrate a layout 40 of an integrated circuit according to an embodiment. For example, FIG. 4A is a top view illustrating the layout 40 including the third PFETs P31 to P34 of FIG. 1B. FIGS. 4B and 4C are examples of cross-sectional view cut along line X1-X1′ of the layout 40 of FIG. 4A. FIG. 4D is a cross-sectional view cut along line Y1-Y1′of the layout 40 of FIG. 4A. Hereinafter, the layout 40 of FIG. 4A includes the third PFETs P31 to P34 of FIG. 1B. FIGS. 4A to 4D are described with reference to FIG. 1B, and the description made above with reference to the drawings is omitted herein.

Referring to FIG. 4A, the layout 40 may include the first device region RX1 and a second device region RX2 extending in the X-axis direction, which are parallel to each other. The first gate electrode G1 and a second gate electrode G2 may extend in the Y-axis direction, may be parallel to each other, and may intersect with the first device region RX1 and the second device region RX2.

The first gate electrode G1 may form two PFETs (e.g., the third PFETs P31 and P34 of FIG. 1B) in the first device region RX1 and the second device region RX2, respectively, and the second gate electrode G2 may form two PFETs (e.g., the third PFETs P32 and P33 of FIG. 1B) in the first device region RX1 and the second device region RX2, respectively. As shown in FIG. 4A, the first active pattern AC1 may extend in the X-axis direction in the first device region RX1 and intersect with the first gate electrode G1 and the second gate electrode G2. In an embodiment, a second active pattern AC2 may extend in the X-axis direction in the second device region RX2 and intersect with the first gate electrode G1 and the second gate electrode G2.

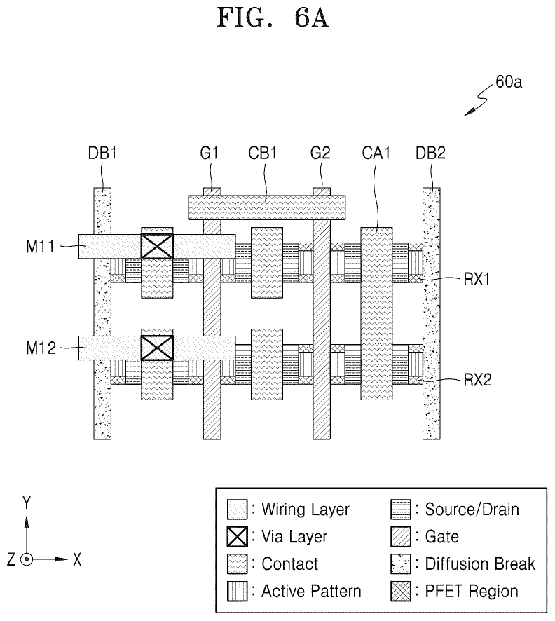

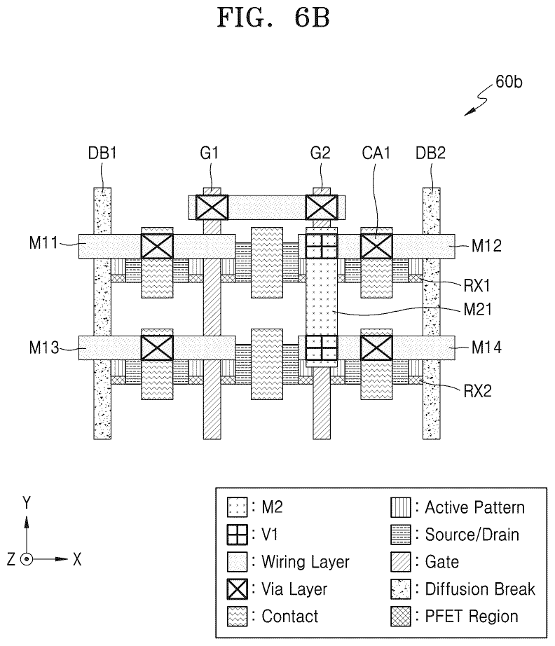

As shown in FIG. 4A, the two PFETs formed by the first gate electrode G1 and the second gate electrode G2 in the first device region RX1 may share one source/drain (i.e., the second source/drain SD2 of FIGS. 4B and 4C), and the two PFETs formed by the first gate electrode G1 and the second gate electrode G2 in the second device region RX2 may share one source/drain. The first gate electrode G1 may be electrically connected to the second gate electrode G2 through a fourth pattern M14 of the first wiring layer M1, and the fourth pattern M14 may be included in the node N4 of FIG. 1B. The first gate electrode G1 and the second gate electrode G2 may have the same width (i.e., a length in the X-axis direction), and the four transistors, i.e., the third PFETs P31 to P34, formed by the first gate electrode G1 and the second gate electrode G2 may have the same channel length. In some embodiments, as described below with reference to FIGS. 6A and 6B, a source/drain of a PFET in the first device region RX1 may be electrically connected to a source/drain of a PFET in the second device region RX2 via a pattern (not shown) extending in the Y-axis direction. As shown in FIG. 4A, the patterns of the first wiring layer M1 may extend in the X-axis direction.

The first diffusion break DB1 and the second diffusion break DB2 may extend in the Y-axis direction and intersect with the first device region RX1 and the second device region RX2. As shown in FIG. 4A, the first gate electrode G1 and the second gate electrode G2 may extend in the Y-axis direction between the first diffusion break DB1 and the second diffusion break DB2.

Referring to FIGS. 4B and 4C, on a substrate SUB, the first gate electrode G1 and the second gate electrode G2 may extend in the Y-axis direction and the first active pattern AC1 may extend in the X-axis direction. The first source/drain SD1 may be between the first diffusion break DB1 and the first gate electrode G1, the second source/drain SD2 may be between the first gate electrode G1 and the second gate electrode G2, and a third source/drain SD3 may be between the second gate electrode G2 and the second diffusion break DB2. The first contact CA1, the second contact CA2, and a third contact CA3 may be on the first source/drain SD1, the second source/drain SD2, and the third source/drain SD3, respectively. A first via V01 may be on the first contact CA1, and the first pattern M11 of the first wiring layer M1 may be electrically connected to the first source/drain SD1 through the first via V01 and the first contact CA1. A second via V02 may be on the third contact CA3, and the second pattern M12 of the first wiring layer M1 may be electrically connected to the third source/drain SD3 through the second via V02 and the third contact CA3.

In some embodiments, the layout 40 may include a pattern extending on the backside of the substrate SUB. For example, as shown in FIG. 4C, in the layout 40, beneath the substrate SUB, a first backside pattern BM11 and a second backside pattern BM12 may extend in a first backside wiring layer BM1 and a backside interlayer dielectric (BILD) may be disposed between the first backside pattern BM11 and the second backside pattern BM12. A first backside contact BC1 may extend in the Z-axis direction by penetrating the substrate SUB between the first source/drain SD1 and the first backside pattern BM11, and the first backside pattern BM11 may be electrically connected to the first source/drain SD1 through the first backside contact BC1. A second backside contact BC2 may extend in the Z-axis direction by penetrating the substrate SUB between the third source/drain SD3 and the second backside pattern BM12, and the second backside pattern BM12 may be electrically connected to the third source/drain SD3 through the second backside contact BC2. Backside contacts and backside patterns may be disposed under a certain rule due to uniform transistors, and problems due to non-uniformity of the backside contacts and the backside patterns in the layout 40 may be resolved.

Referring to FIG. 4D, the first source/drain SD1 and a fourth source/drain SD4 may be on the substrate SUB. As shown in FIG. 4D, the first source/drain SD1 may be included in the first device region RX1, and the fourth source/drain SD4 may be included in the second device region RX2. The first contact CA1 and a fourth contact CA4 may be on the first source/drain SD1 and the fourth source/drain SD4, respectively. The first via V01 may be on the first contact CA1, and the first pattern M11 of the first wiring layer M1 may be electrically connected to the first source/drain SD1 through the first via V01 and the first contact CA1. A third via V03 may be on the fourth contact CA4, and a third pattern M13 of the first wiring layer M1 may be electrically connected to the fourth source/drain SD4 through the third via V03 and the fourth contact CA4.

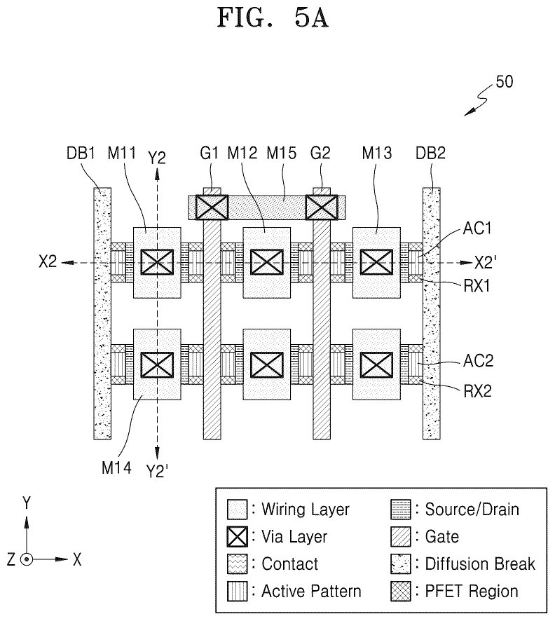

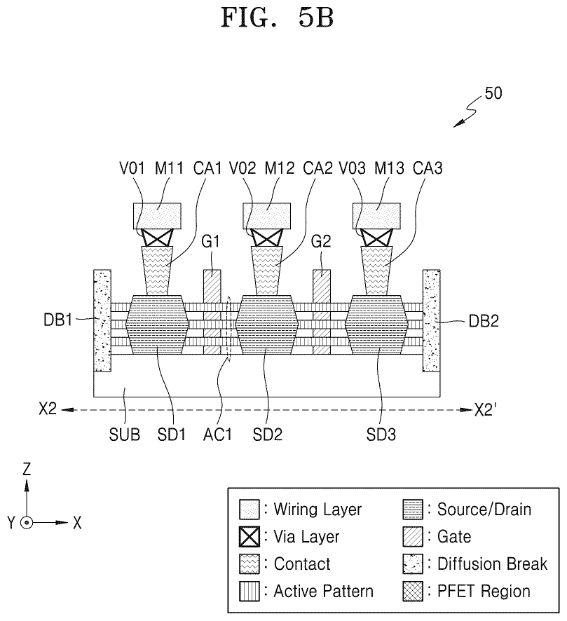

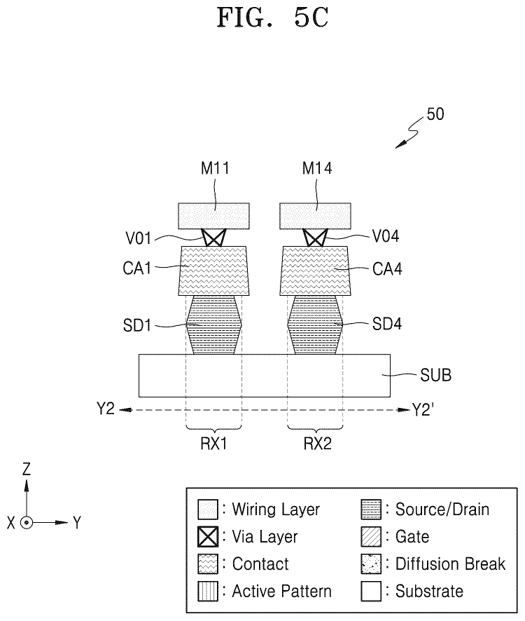

FIGS. 5A to 5C illustrate a layout 50 of an integrated circuit according to an embodiment. For example, FIG. 5A is a top view illustrating the layout 50 including the third PFETs P31 to P34 of FIG. 1B, FIG. 5B is a cross-sectional view cut along line X2-X2′ of the layout 50 of FIG. 5A, and FIG. 4C is a cross-sectional view cut along line Y2-Y2′ of the layout 50 of FIG. 5A. Hereinafter, the layout 50 of FIG. 5A includes the third PFETs P31 to P34 of FIG. 1B. FIGS. 5A to 5C are described with reference to FIG. 1B, and the description made above with reference to the drawings is omitted herein.

Referring to FIG. 5A, the layout 50 may include the first device region RX1 and the second device region RX2 extending in the X-axis direction, which are parallel to each other. The first gate electrode G1 and the second gate electrode G2 may extend in the Y-axis direction, may be parallel to each other, and may intersect with the first device region RX1 and the second device region RX2. The first gate electrode G1 may form two PFETs (e.g., the third PFETs P31 and P34 of FIG. 1B) in the first device region RX1 and the second device region RX2, respectively, and the second gate electrode G2 may form two PFETs (e.g., the third PFETs P32 and P33 of FIG. 1B) in the first device region RX1 and the second device region RX2, respectively. As shown in FIG. 5A, the first active pattern AC1 may extend in the X-axis direction in the first device region RX1 and intersect with the first gate electrode G1 and the second gate electrode G2. In an embodiment, the second active pattern AC2 may extend in the X-axis direction in the second device region RX2 and intersect with the first gate electrode G1 and the second gate electrode G2.

As shown in FIG. 5A, the two PFETs formed by the first gate electrode G1 and the second gate electrode G2 in the first device region RX1 may share one source/drain (i.e., the second source/drain SD2 of FIG. 5B), and the two PFETs formed by the first gate electrode G1 and the second gate electrode G2 in the second device region RX2 may share one source/drain. The first gate electrode G1 may be electrically connected to the second gate electrode G2 through a fifth pattern M15 of the first wiring layer M1, and the fifth pattern M15 may be included in the node N4 of FIG. 1B. The first gate electrode G1 and the second gate electrode G2 may have the same width (i.e., a length in the X-axis direction), and the four transistors, i.e., the third PFETs P31 to P34, formed by the first gate electrode G1 and the second gate electrode G2 may have the same channel length. In some embodiments, as described below with reference to FIGS. 6A and 6B, a source/drain of a PFET in the first device region RX1 may be electrically connected to a source/drain of a PFET in the second device region RX2 via a pattern (not shown) extending in the Y-axis direction.

Compared to the layout 40 of FIG. 4A, the layout 50 of FIG. 5A may include patterns extending on the first wiring layer M1 in the Y-axis direction. For example, the first pattern M11, the second pattern M12, the third pattern M13, and the fourth pattern M14 of the first wiring layer M1 may extend in the Y-axis direction. The layout 40 of FIG. 4A may provide high routability in the first wiring layer M1, and the layout 50 of FIG. 5A may provide high current density in the first wiring layer M1.

The first diffusion break DB1 and the second diffusion break DB2 may extend in the Y-axis direction and intersect with the first device region RX1 and the second device region RX2. As shown in FIG. 5A, the first gate electrode G1 and the second gate electrode G2 may extend in the Y-axis direction between the first diffusion break DB1 and the second diffusion break DB2.

Referring to FIG. 5B, on the substrate SUB, the first gate electrode G1 and the second gate electrode G2 may extend in the Y-axis direction and the first active pattern AC1 may extend in the X-axis direction. The first source/drain SD1 may be between the first diffusion break DB1 and the first gate electrode G1, the second source/drain SD2 may be between the first gate electrode G1 and the second gate electrode G2, and the third source/drain SD3 may be between the second gate electrode G2 and the second diffusion break DB2. The first contact CA1, the second contact CA2, and the third contact CA3 may be on the first source/drain SD1, the second source/drain SD2, and the third source/drain SD3, respectively. The first via V01 may be on the first contact CA1, and the first pattern M11 of the first wiring layer M1 may be electrically connected to the first source/drain SD1 through the first via V01 and the first contact CA1. The second via V02 may be on the second contact CA2, and the second pattern M12 of the first wiring layer M1 may be electrically connected to the second source/drain SD2 through the second via V02 and the second contact CA2. The third via V03 may be on the third contact CA3, and the third pattern M13 of the first wiring layer M1 may be electrically connected to the third source/drain SD3 through the third via V03 and the third contact CA3.

Referring to FIG. 5C, the first source/drain SD1 and the fourth source/drain SD4 may be on the substrate SUB. As shown in FIG. 5C, the first source/drain SD1 may be included in the first device region RX1, and the fourth source/drain SD4 may be included in the second device region RX2. The first contact CA1 and the fourth contact CA4 may be on the first source/drain SD1 and the fourth source/drain SD4, respectively. The first via V01 may be on the first contact CA1, and the first pattern M11 of the first wiring layer M1 may be electrically connected to the first source/drain SD1 through the first via V01 and the first contact CA1. A fourth via V04 may be on the fourth contact CA4, and the fourth pattern M14 of the first wiring layer M1 may be electrically connected to the fourth source/drain SD4 through the fourth via V04 and the fourth contact CA4.

FIGS. 6A and 6B are top views illustrating layouts 60a and 60b of integrated circuits according to embodiments. For example, the top views of FIGS. 6A and 6B respectively illustrate the layouts 60a and 60b each including the third PFETs P31 to P34 of FIG. 1B. Hereinafter, each of the layouts 60a and 60b of FIGS. 6A and 6B includes the third PFETs P31 to P34 of FIG. 1B. FIGS. 6A and 6B are described with reference to FIG. 1B, and the description made above with reference to the drawings is omitted herein.

Referring to FIG. 6A, the layout 60a may include the first device region RX1 and the second device region RX2 extending in the X-axis direction, which are parallel to each other. The first gate electrode G1 and a second gate electrode G2 may extend in the Y-axis direction, may be parallel to each other, and may intersect with the first device region RX1 and the second device region RX2. The first gate electrode G1 may form two PFETs, i.e., the third PFETs P31 and P34, in the first device region RX1 and the second device region RX2, respectively, and the second gate electrode G2 may form two PFETs, i.e., the third PFETs P32 and P33, in the first device region RX1 and the second device region RX2, respectively. As shown in FIG. 6A, the first active pattern AC1 may extend in the X-axis direction in the first device region RX1 and intersect with the first gate electrode G1 and the second gate electrode G2. In an embodiment, the second active pattern AC2 may extend in the X-axis direction in the second device region RX2 and intersect with the first gate electrode G1 and the second gate electrode G2.

The first pattern M11 of the first wiring layer M1 may be electrically connected to the source of the third PFET P31 in the first device region RX1, and the second pattern M12 of the first wiring layer M1 may be electrically connected to the drain of the third PFET P34 in the second device region RX2. The first pattern M11 and the second pattern M12 of the first wiring layer M1 may be electrically disconnected from each other. Therefore, the source of the third PFET P31 is electrically disconnected from the drain of the third PFET P34. The first diffusion break DB1 and the second diffusion break DB2 may extend in the Y-axis direction and intersect with the first device region RX1 and the second device region RX2. As shown in FIG. 6A, the first gate electrode G1 and the second gate electrode G2 may extend in the Y-axis direction between the first diffusion break DB1 and the second diffusion break DB2.

In some embodiments, a contact may be used as a wiring. For example, as shown in FIG. 6A, the first gate electrode G1 may be electrically connected to the second gate electrode G2 through a gate contact CB1 extending in the X-axis direction. Accordingly, the first gate electrode G1 and the second gate electrode G2 may be commonly connected to the node N4. In an embodiment, the drain of the third PFET P32 in the first device region RX1 may be electrically connected to the source of the third PFET P33 in the second device region RX2 through the first contact CA1 extending in the Y-axis direction. Accordingly, the third PFETs P31 to P34 may be connected in series to each other.

Referring to FIG. 6B, the layout 60b may include the first device region RX1 and the second device region RX2 extending in the X-axis direction, which are parallel to each other. The first gate electrode G1 and the second gate electrode G2 may extend in the Y-axis direction, may be parallel to each other, and may intersect with the first device region RX1 and the second device region RX2. The first gate electrode G1 may form two PFETs, i.e., the third PFETs P31 and P34, in the first device region RX1 and the second device region RX2, respectively, and the second gate electrode G2 may form two PFETs, i.e., the third PFETs P32 and P33, in the first device region RX1 and the second device region RX2, respectively. As shown in FIG. 6B, the first active pattern AC1 may extend in the X-axis direction in the first device region RX1 and intersect with the first gate electrode G1 and the second gate electrode G2. In an embodiment, the second active pattern AC2 may extend in the X-axis direction in the second device region RX2 and intersect with the first gate electrode G1 and the second gate electrode G2.

The first pattern M11 of the first wiring layer M1 may be electrically connected to the source of the third PFET P31 in the first device region RX1, and the third pattern M13 of the first wiring layer M1 may be electrically connected to the drain of the third PFET P34 in the second device region RX2. The first pattern M11 may be electrically disconnected from the third pattern M13. Therefore, the source of the third PFET P31 is electrically disconnected from the drain of the third PFET P34. The first diffusion break DB1 and the second diffusion break DB2 may extend in the Y-axis direction and intersect with the first device region RX1 and the second device region RX2. As shown in FIG. 6B, the first gate electrode G1 and the second gate electrode G2 may extend in the Y-axis direction between the first diffusion break DB1 and the second diffusion break DB2.

In some embodiments, transistors may be connected in series to each other via patterns of a wiring layer. For example, as shown in FIG. 6B, the second pattern M12 of the first wiring layer M1 may be electrically connected to the drain of the third PFET P32 in the first device region RX1, and the fourth pattern M14 of the first wiring layer M1 may be electrically connected to the source of the third PFET P33 in the second device region RX2. A pattern M21 of a second wiring layer M2 may extend in the Y-axis direction and be respectively connected to the second pattern M12 and the fourth pattern M14 of the first wiring layer M1 through vias of a second via layer V1. Accordingly, the drain of the third PFET P32 in the first device region RX1 may be electrically connected to the source of the third PFET P33 in the second device region RX2 through the pattern M21 of the second wiring layer M2 extending in the Y-axis direction, and the third PFETs P31 to P34 may be connected in series to each other.

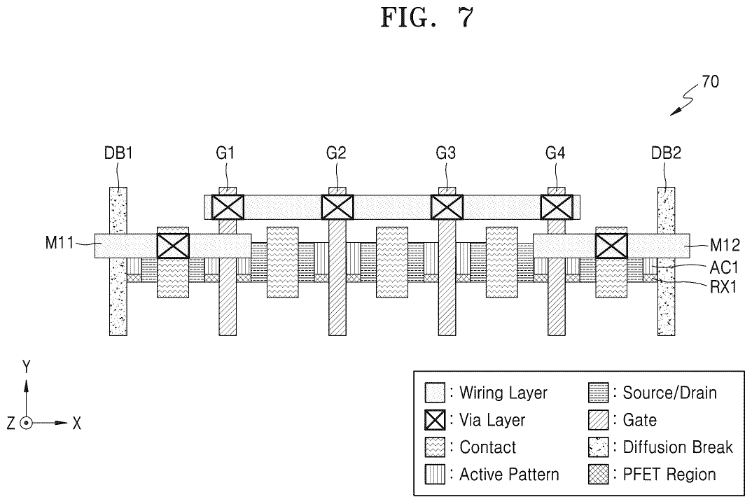

FIG. 7 is a top view illustrating a layout 70 of an integrated circuit according to an embodiment. For example, the top view of FIG. 7 shows the layout 70 including the third PFETs P31 to P34 of FIG. 1B. Hereinafter, the layout 70 of FIG. 7 includes the third PFETs P31 to P34 of FIG. 1B. FIG. 7 is described with reference to FIG. 1B, and the description made above with reference to the drawings is omitted herein.

Referring to FIG. 7, the layout 70 may include the first device region RX1 extending in the X-axis direction. First to fourth gate electrodes G1 to G4 may extend in the Y-axis direction, may be parallel to each other, and may intersect with the first device region RX1. The first to fourth gate electrodes G1 to G4 may form the third PFETs P31 to P34 in the first device region RX1, respectively. The third PFETs P31 and P32 respectively formed by the first gate electrode G1 and the second gate electrode G2 may share a source/drain. The third PFETs P32 and P33 respectively formed by the second gate electrode G2 and the third gate electrode G3 may share a source/drain. The third PFETs P33 and P34 respectively formed by the third gate electrode G3 and the fourth gate electrode G4 may share a source/drain.

Accordingly, the third PFETs P31 to P34 may be connected in series to each other. As shown in FIG. 7, the first active pattern AC1 may extend in the X-axis direction in the first device region RX1 and intersect with the first to fourth gate electrodes G1 to G4. The first diffusion break DB1 and the second diffusion break DB2 may extend in the Y-axis direction and intersect with the first device region RX1. As shown in FIG. 7, the first to fourth gate electrodes G1 to G4 may extend in the Y-axis direction between the first diffusion break DB1 and the second diffusion break DB2.

The first pattern M11 of the first wiring layer M1 may be electrically connected to the source of the third PFET P31, and the second pattern M12 of the first wiring layer M1 may be electrically connected to the drain of the third PFET P34. The third pattern M13 of the first wiring layer M1 may extend in the X-axis direction and be electrically connected to the first to fourth gate electrodes G1 to G4. Accordingly, the first to fourth gate electrodes G1 to G4 may be commonly connected to the node N4. In an embodiment, the third PFETs P31 to P34 may be formed in two device regions, i.e., the first device region RX1 and the second device region RX2, extending in the X direction and being parallel to each other in the layouts 60a and 60b of FIGS. 6A and 6B. In an embodiment, the third PFETs P31 to P34 may be formed in one device region, i.e., the first device region RX1, in the layout 70 of FIG. 7.

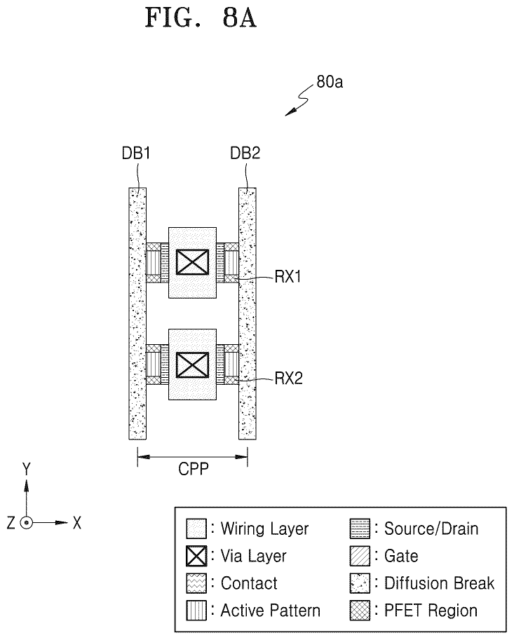

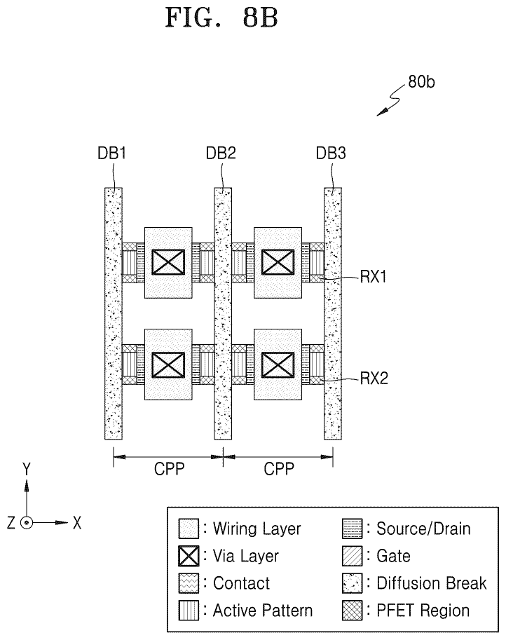

FIGS. 8A and 8B are top views illustrating layouts 80a and 80b of integrated circuits according to embodiments. For example, the top views of FIGS. 8A and 8B respectively show the layouts 80a and 80b each including a structure, which may be inserted between transistors. Hereinafter, the description made above with reference to the drawings is omitted in a description of FIGS. 8A and 8B.

As described above with reference to the drawings, transistors adjacent in the X-axis direction may be isolated from each other by a diffusion break. When an expanded space is required between transistors due to an LLE or the like, the structures shown in FIGS. 8A and 8B may be inserted between the transistors. Herein, like the structures shown in FIGS. 8A and 8B, a structure inserted between transistors may be referred to as a filler or a filler structure.

Referring to FIG. 8A, the layout 80a may include the first device region RX1 and the second device region RX2 extending in the X-axis direction. The first diffusion break DB1 and the second diffusion break DB2 may extend in the Y-axis direction, may be parallel to each other at the pitch CPP of gate electrodes, and may intersect with the first device region RX1 and the second device region RX2. Accordingly, a transistor adjacent to the first diffusion break DB1 may be spaced apart in the X-axis direction from a transistor adjacent to the second diffusion break DB2 so as to be farther than the pitch CPP.

Referring to FIG. 8B, the layout 80b may include the first device region RX1 and the second device region RX2 extending in the X-axis direction. The first diffusion break DB1, the second diffusion break DB2, and a third diffusion break DB3 may extend in the Y-axis direction, may be parallel to each other at the pitch CPP of gate electrodes, and may intersect with the first device region RX1 and the second device region RX2. Accordingly, a transistor adjacent to the first diffusion break DB1 may be spaced apart in the X-axis direction from a transistor adjacent to the third diffusion break DB3 so as to be farther than twice the pitch CPP.

Like the layout 80b of FIG. 8B, the structure of FIG. 8A may be repeated according to a space required between transistors, and accordingly, a filler structure may also conform to a certain rule. Although FIGS. 8A and 8B show diffusion breaks intersecting with two device regions, i.e., the first device region RX1 and the second device region RX2, extending in parallel to each other, a structure including diffusion breaks intersecting with one device region is also possible.

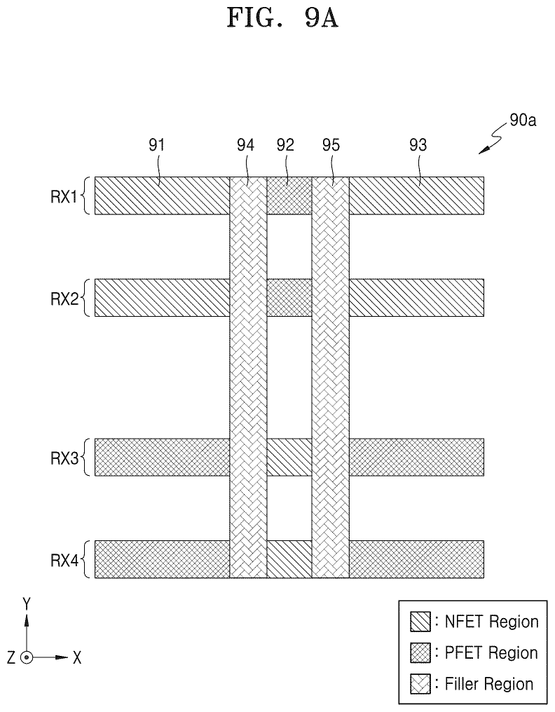

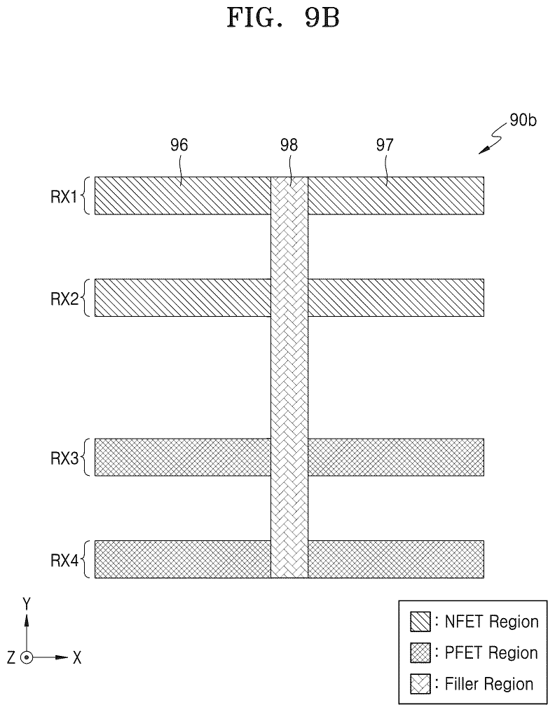

FIGS. 9A and 9B are top views illustrating layouts 90a and 90b of integrated circuits according to embodiments. For example, the top views of FIGS. 9A and 9B show the layouts 90a and 90b of integrated circuits each including a filler structure. As described above with reference to FIGS. 8A and 8B, a filler structure may be inserted between transistors, and accordingly, a space may be ensured between the transistors. Hereinafter, a description made with reference to FIGS. 9A and 9B is not repeated.

Referring to FIG. 9A, first to fourth device regions RX1 to RX4 may extend in the X-axis direction and may be parallel to each other. In some embodiments, a filler structure may be inserted between transistors having different conductive-type channels, i.e., different types of transistors. For example, as shown in FIG. 9A, the first device region RX1 may include first to third regions 91 to 93. NFETs may be formed in the first region 91 and the third region 93, and PFETs may be formed in the second region 92 between the first region 91 and the third region 93. As shown in FIG. 9A, a fourth region 94 may be formed between the first region 91 having NFETs formed therein and the second region 92 having PFETs formed therein. In an embodiment, a fifth region 95 may be formed between the second region 92 having the PFETs formed therein and the third region 93 having NFETs formed therein. The fourth region 94 and the fifth region 95 may include the structure described above with reference to FIG. 8A or 8B.

Referring to FIG. 9B, the first to fourth device regions RX1 to RX4 may extend in the X-axis direction and may be parallel to each other. In some embodiments, a filler structure may be inserted between transistors having the same conductive-type channels, i.e., the same type of transistors. For example, the first device region RX1 may include a sixth region 96 and a seventh region 97, and NFETs may be formed in the sixth region 96 and the seventh region 97. To prevent influences, e.g., an LLE, noise, and the like, between NFETs formed in the sixth region 96 and NFETs formed in the seventh region 97, an eighth region 98 may be inserted between the sixth region 96 and the seventh region 97. The eighth region 98 may include the structure described above with reference to FIG. 8A or 8B.

In some embodiments, in the layouts 90a and 90b of FIGS. 9A and 9B, gate electrodes and diffusion breaks may extend in the Y-axis direction and may be parallel to each other at a certain pitch. In some embodiments, in the layouts 90a and 90b of FIGS. 9A and 9B, the gate electrodes may have the same width and correspond to, for example, the minimum gate width.

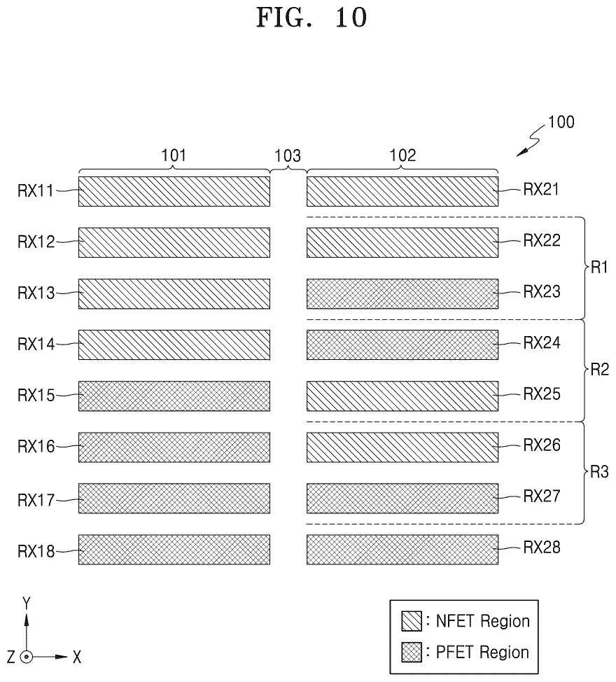

FIG. 10 is a top view illustrating a layout 100 of an integrated circuit according to an embodiment. For example, the top view of FIG. 10 shows the layout 100 of the integrated circuit including an analog circuit and a digital circuit. Hereinafter, the description made above with reference to the drawings is omitted herein.

In some embodiments, the integrated circuit may include an analog circuit configured to process an analog signal and a digital circuit configured to process a digital signal. For example, as shown in FIG. 10, the layout 100 may include a first region 101 corresponding to the analog circuit and a second region 102 corresponding to the digital circuit. In an embodiment, the layout 100 may include a third region 103 between the first region 101 and the second region 102. The first region 101 may include a plurality of first device regions RX11 to RX18 extending in the X-axis direction, and the second region 102 may include a plurality of second device regions RX21 to RX28 extending in the X-axis direction.

The digital circuit may include a logic circuit configured to process a digital signal, and the logic circuit may be implemented by standard cells in the layout 100. For example, a semiconductor design tool (e.g., a logic synthesis tool) may perform logic synthesis, by referring to a cell library, from register transfer level (RTL) data created by a hardware description language (HDL), such as very high speed integrated circuits (VHSIC) HDL (VHDL) or Verilog, and generate netlist data including a bitstream or netlist. The cell library may define a plurality of standard cells. A standard cell is a unit of layout and may be designed to perform a predefined function, and standard cells may be aligned and arranged on rows. For example, the semiconductor design tool may align and place standard cells defined in the netlist data on first to third rows R1 to R3 in the second region 102 of FIG. 10.

A standard cell may include an NFET and a PFET, and accordingly, a device region having a PFET formed therein and a device region having an NFET formed therein may be included in one row. For example, as shown in FIG. 10, the second device region RX22 having an NFET formed therein and the second device region RX23 having a PFET formed therein may extend in the X-axis direction on the first row R1. The second device region RX24 having a PFET formed therein and the second device region RX25 having an NFET formed therein may extend in the X-axis direction on the second row R2. The second device region RX26 having an NFET formed therein and the second device region RX27 having a PFET formed therein may extend in the X-axis direction on the third row R3. As shown in FIG. 10, a pair of second device regions each having an NFET formed therein and a pair of second device regions each having a PFET formed therein may be alternately arranged in the Y-axis direction.

As described above with reference to the drawings, device regions may extend in the X-axis direction in the first region 101. For example, as shown in FIG. 10, in the first region 101, the first device regions RX11 to RX14 each having an NFET formed therein may extend in the X-axis direction and may be parallel to each other. The first device regions RX15 to RX18 each having a PFET formed therein may extend in the X-axis direction and may be parallel to each other. Unlike the second region 102 in which a pair of second device regions each having an NFET formed therein and a pair of second device regions each having a PFET formed therein are alternately arranged in the Y-axis direction, first device regions each having an NFET formed therein and first device regions each having a PFET formed therein may be configured according to a design.

In some embodiments, the plurality of first device regions in the first region 101 and the plurality of second device regions in the second region 102 may be aligned in the X-axis direction. For example, as shown in FIG. 10, the plurality of first device regions RX11 to RX18 and the plurality of second device regions RX21 to RX28 may be aligned in the X-axis direction, respectively. Accordingly, as shown in FIG. 10, the first device region RX11 and the second device region RX21 each having NFETs formed therein may be aligned in the X-axis direction, and the first device region RX13 having NFETs formed therein and the second device region RX23 having PFETs formed therein may be aligned in the X-axis direction.

In some embodiments, the pitch of gate electrodes extending in the Y-axis direction in the first region 101 may be the same as the pitch of gate electrodes extending in the Y-axis direction in the second region 102. In some embodiments, the gate electrodes extending in the Y-axis direction in the first region 101 and the gate electrodes extending in the Y-axis direction in the second region 102 may have the same width (i.e., the same length in the X-axis direction), for example, the minimum gate width of the layout 100. In some embodiments, the third region 103 may include a filler structure as described above with reference to FIGS. 8A and 8B. In some embodiments, the first region 101 and the second region 102 may include a wide gate electrode extending in the Y-axis direction to be adjacent to the third region 103, and the wide gate electrode may have a width corresponding to a multiple of the pitch of the gate electrodes having the minimum gate width.

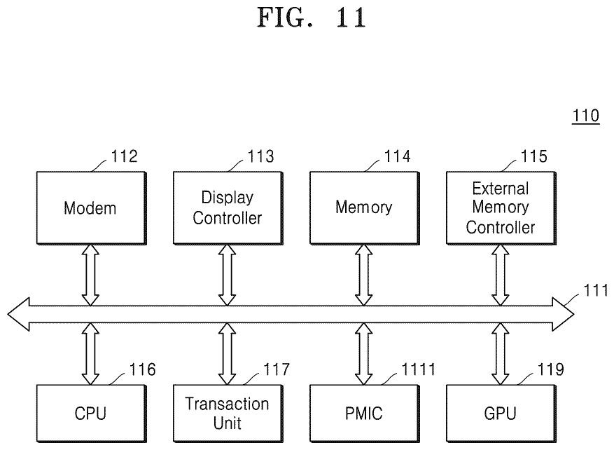

FIG. 11 is a block diagram illustrating a system on chip (SoC) 110 according to an embodiment. The SoC 110 is a semiconductor device and may include an integrated circuit according to an embodiment. The SoC 110 is a single chip in which complex blocks, such as intellectual properties (IPs), configured to perform various functions are implemented, and may efficiently provide various channel lengths according to embodiments and have high efficiency and reliability. Referring to FIG. 11, the SoC 110 may include a modem 112, a display controller 113, a memory 114, an external memory controller 115, a central processing unit (CPU) 116, a transaction unit 117, a power management integrated circuit (PMIC) 118, and a graphics processing unit (GPU) 119, and the function blocks of the SoC 110 may communicate with each other through a system bus 111.

A “unit” used in the disclosure (for example, the transaction unit 117) refers to a hardware component such as a processor or a circuit, and/or a software component executed by a hardware component such as a processor. The “unit” may be implemented by a program that is stored in a storage medium which may be addressed, and is executed by a processor. For example, the “unit” may be implemented by components such as software components, object-oriented software components, class components, and task components, processes, functions, attributes, procedures, sub-routines, segments of a program code, drivers, firmware, a micro code, a circuit, data, a database, data structures, tables, arrays and parameters.

The CPU 116 capable of controlling, on the highest layer, an operation of the SoC 110 may control operations of the other function blocks, i.e., the modem 112, the display controller 113, the memory 114, the external memory controller 115, the transaction unit 117, the PMIC 118, and the GPU 119. The modem 112 may demodulate a signal received from the outside of the SoC 110 or modulate a signal generated inside the SoC 110 and transmit the modulated signal to the outside. The external memory controller 115 may control an operation of transmitting and receiving data to and from an external memory device connected to the SoC 110. For example, a program and/or data stored in the external memory device may be provided to the CPU 116 or the GPU 119 under control by the external memory controller 115. The GPU 119 may execute a program command (instructions) related to graphics processing. The GPU 119 may receive graphics data through the external memory controller 115 and transmit graphics data processed by the GPU 119 to the outside of the SoC 110 through the external memory controller 115. The transaction unit 117 may monitor a data transaction of each function block, and the PMIC 118 may control power to be supplied to each function block, under control by the transaction unit 117. The display controller 113 may transmit data generated inside the SoC 110 to a display (or a display device) outside the SoC 110 by controlling the display. The memory 114 may include a nonvolatile memory, such as electrically erasable programmable read-only memory (EEPROM) or flash memory, or a volatile memory, such as dynamic random access memory (DRAM) or static random access memory (SRAM).

While the disclosure has been particularly shown and described with reference to embodiments thereof, it will be understood that various changes in form and details may be made therein without departing from the spirit and scope of the following claims.

1. An integrated circuit comprising:
a first device region and a second device region extending parallel to each other on a substrate in a first direction;
a first gate electrode extending in a second direction and intersecting with the first device region and the second device region;
a first transistor comprising the first gate electrode and a first channel having a first conductive-type in the first device region; and
a second transistor comprising the first gate electrode and a second channel having the first conductive-type in the second device region,
wherein a first source/drain region of the first transistor is electrically connected to a first source/drain region of the second transistor, and
wherein a second source/drain region of the first transistor is electrically disconnected from a second source/drain region of the second transistor.

2. The integrated circuit of claim 1, further comprising:
a second gate electrode extending in the second direction and intersecting with the first device region and the second device region;
a third transistor comprising the second gate electrode and a third channel having the first conductive-type in the first device region; and a fourth transistor comprising the second gate electrode and a fourth channel having the first conductive-type in the second device region.

3. The integrated circuit of claim 2, wherein the first gate electrode and the second gate electrode are adjacent to each other in the first direction and are electrically connected to each other.

4. The integrated circuit of claim 3, further comprising a contact extending in the first direction and connected to the first gate electrode and the second gate electrode.

5. The integrated circuit of claim 3, further comprising a pattern extending on a wiring layer in the first direction and electrically connected to the first gate electrode and the second gate electrode.

6. The integrated circuit of claim 2, wherein the first transistor, the second transistor, the third transistor, and the fourth transistor are connected in series to each other.

7. The integrated circuit of claim 1, further comprising a contact extending in the second direction and connected to the first source/drain region of the first transistor and the first source/drain region of the second transistor.

8. The integrated circuit of claim 1, further comprising a pattern extending on a wiring layer in the second direction and electrically connected to the first source/drain region of the first transistor and the first source/drain region of the second transistor.

9. The integrated circuit of claim 1, further comprising:
a second gate electrode extending in the second direction and intersecting with the first device region and the second device region; and
a first diffusion break and a second diffusion break extending parallel to each other in the second direction between the first gate electrode and the second gate electrode, and intersecting with the first device region and the second device region,
wherein the first diffusion break and the second diffusion break comprise an insulating material.

10. (canceled)

11. The integrated circuit of claim 9, further comprising:
a third transistor comprising the second gate electrode and a third channel having the first conductive-type in the first device region, and
a fourth transistor comprising the second gate electrode and the fourth channel having the first conductive-type in the second device region.

12. The integrated circuit of claim 9, further comprising:
a third transistor comprising the second gate electrode and a third channel having a second conductive-type in the first device region, and
a fourth transistor comprising the second gate electrode and a fourth channel having the second conductive-type in the second device region.

13. (canceled)

14. The integrated circuit of claim 1, further comprising a pattern electrically connected to the first source/drain region of the first transistor and extending in the second direction on a first wiring layer, which is closest to the first gate electrode, among wiring layers.

15. The integrated circuit of claim 1, further comprising a backside contact penetrating the substrate from the first source/drain region of the first transistor.

16. The integrated circuit of claim 1, wherein the first device region is adjacent to the second device region in the second direction.

17. The integrated circuit of claim 1, wherein the first gate electrode has a shortest length in the second direction among gate electrodes of the integrated circuit.

18. An integrated circuit comprising:
a first device region extending on a substrate in a first direction;
a first gate electrode and a second gate electrode extending parallel to each other in a second direction, and intersecting with the first device region;
a first transistor comprising the first gate electrode and a first channel having a first conductive-type in the first device region; and
a second transistor comprising the second gate electrode and a second channel having the first conductive-type in the first device region,
wherein the first transistor and the second transistor are configured to share a first source/drain region between the first gate electrode and the second gate electrode, and
wherein the first gate electrode is electrically connected to the second gate electrode.

19. (canceled)

20. (canceled)

21. The integrated circuit of claim 18, further comprising:
a third gate electrode extending in the second direction and intersecting with the first device region; and
a third transistor comprising the third gate electrode and a third channel having the first conductive-type in the first device region,
wherein the second transistor and the third transistor are configured to share a source/drain region between the second gate electrode and the third gate electrode, and
wherein the third gate electrode is electrically connected to the second gate electrode.

22. (canceled)

23. (canceled)

24. (canceled)

25. (canceled)

26. (canceled)

27. (canceled)

28. (canceled)

29. (canceled)

30. An integrated circuit comprising:
a first transistor and a second transistor having a first conductive-type channel and connected in series to each other; and
a third transistor and a fourth transistor having a second conductive-type channel and connected in series to each other,
wherein a first gate of the first transistor and a second gate of the second transistor are electrically connected to a first node, and
wherein a third gate of the third transistor and a fourth gate of the fourth transistor are electrically connected to a second node.

31. The integrated circuit of claim 30, wherein the first gate, the second gate, the third gate, and the fourth gate have a minimum gate width in the integrated circuit.

32. The integrated circuit of claim 30, further comprising a fifth transistor comprising the first conductive-type channel and connected in series to the first transistor and the second transistor,
wherein a fifth gate of the fifth transistor is electrically connected to the first node.

33. (canceled)
